(19) United States
(12) Patent Application Publication
(10) Pub. No.: US 2008/0173975 A1
(43) Pub. Date: Jul. 24, 2008

(54) PROGRAMMABLE RESISTOR, SWITCH OR VERTICAL MEMORY CELL

(75) Inventors: Fen Chen, Williston, VT (US); Armin Fischer, Muenchen (DE); Jason P. Gill, Essex Junction, VT (US)

Correspondence Address: FREDERICK W. GIBB, III;Gibb & Rahman, LLC, 2568-A RIVA ROAD, SUITE 304, ANNAPOLIS, MD, 21401, US

(73) Assignees: INTERNATIONAL BUSINESS MACHINES CORPORATION, Armonk, NY (US); INFINEON TECHNOLOGIES NORTH AMERICA CORPORATION, Milpitas, CA (US)

(21) Appl. No.: 11/625,607

(22) Filed: Jan. 22, 2007

(51) Int. Cl. H01L 29/00; H01L 21/02

(52) U.S. Cl. 257/529; 438/381; 257/E21.003; 257/E29.001

(57) ABSTRACT

Disclosed are embodiments of a device and method of forming the device that utilize metal ion migration under controllable conditions. The device embodiments comprise two metal electrodes separated by one or more different dielectric materials. One electrode is sealed from the dielectric material, the other is not. The device is adapted to allow controlled migration of embedded metal ions from the unsealed electrode into dielectric material to form a conductive path under field between the electrodes and, thereby, to decrease the resistance of the dielectric material. Reversing the field causes the metal ions to reverse their migration, to break the conductive metallic path between the electrodes and, thereby, to increase the resistance of the dielectric material. Thus, the device can comprise a simple switch or programmable resistor. Additionally, by monitoring the resistance change, a two-state, two-terminal, silicon technology-compatible, flash memory device with a very simple tuning process can be created.

### BACKGROUND

1. Field of the Invention

The embodiments of the invention generally relate to programmable resistors, and, more particularly, to a field programmable resistor or switch that can be incorporated into a memory array as a memory cell.

2. Description of the Related Art

Existing limitations of current memory technologies represent opportunities for alternatives. Current floating-gate flash memories are proving especially difficult to scale. Static random access memory (SRAM) arrays are looking increasingly vulnerable to soft errors, and dynamic random access memory (DRAM) arrays are slow and require a significant amount of power for operation. Phase change random access memory (PCRAM) arrays are an emerging non-volatile memory technology, which attempts to overcome the limitations of SRAM and DRAM arrays. This PCRAM technology is based on a structure called a phase change element (PCE), which is generally understood to be a programmable resistor. For example, the phase change material in each PCE can be programmed to store one binary state (e.g., “0”) at a low resistance crystalline state and another binary state (e.g., “1”) at a high resistance amorphous state. Additionally, such phase change materials can be programmed to multiple different resistances states (e.g., a high resistance completely amorphous state, multiple mid-resistance semi-amorphous/semi-crystalline states, and a low resistance completely crystalline state) in order to store more than just a single bit (0,1) of information. However, PCEs are not field programmable as they require a special tuning process in which electrical impulses must be applied to the phase change materials in order to “program” them to exhibit the desired resistive properties to store data. Additionally, the integration of PCE memory with existing silicon-based integrated circuits and the high current/voltage operation mode pose concerns for real-world PCE memory applications.

Therefore, there is a need in the art for a device (e.g., a programmable resistor) that is both field programmable and can be incorporated into a non-volatile memory array in a manner similar to that of a PCE such that it overcomes the limits of current SRAM and DRAM technology (i.e., such that it exhibits fast write and read, it is capable of high write/erase cycles, it is compatible with current silicon technology, it exhibits soft error immunity, it is capable of scaling, etc.).

### SUMMARY

In view of the foregoing, disclosed herein are embodiments of a device and a method of forming the device that utilize metal ion migration (e.g., copper (Cu) ion migration) under controllable conditions to form a programmable resistor or switch. Specifically, the embodiments of the device comprise two metal electrodes (e.g., Cu electrodes) separated by one or more different dielectric materials (e.g., a low-k dielectric material with relatively high diffusivity to copper). One electrode is sealed from the dielectric material, the other is not. The device is adapted to allow controlled migration of embedded metal ions from the unsealed electrode into dielectric material to form a more conductive path with the accumulation of metal ions in dielectric under field between the electrodes in a matter of nanoseconds and, thereby, to decrease the resistivity and hence the resistance of the dielectric material. Reversing the field causes the metal ions to reverse their migration, to break the conductive path between the electrodes, and, thereby, to increase the resistance of the dielectric material. Thus, the device can comprise a simple switch or programmable resistor. Additionally, by monitoring the resistance change, a two-state, two-terminal, silicon technology-compatible, flash memory device with a very simple tuning process can be created.

More particularly, an embodiment of the device can comprise an isolation layer having a first side and a second side. A cell, such as a via, can extend through the isolation layer from the first side to the second side. This cell or via can be filled with a bulk low-k dielectric material or, alternatively, can be filled with multiple layers of at least two different low-k dielectric materials extending vertically between the first side and the second side. The material that forms the isolation layer and the dielectric fill material(s) within the cell can comprise different materials. For example, the dielectric fill material(s) within the cell can comprise low-k dielectric material(s) that have a relatively high copper ion diffusivity. Whereas, the isolation layer can comprise a material that has a relatively low copper ion diffusivity and that adheres well to low-k dielectrics. Optionally, the sidewalls of the cell can be lined with a material that provides a diffusion barrier and that further enhances adhesion of the dielectric fill material(s) within the cell. Lining the cell sidewalls, further allows the isolation layer to be formed using a conventional inter-layer dielectric (e.g., silicon dioxide (SiO₂), which generally also allows for fast diffusion of copper ions). Lining the cell, also allows the same dielectric material to be used in both the isolation layer and the cell without risking copper diffusion into the isolation layer.

The device can further comprise a first metal layer (e.g., a metal electrode, such as a copper electrode) adjacent to the cell on the first side. The interface between the first metal layer and the dielectric fill material(s) is permeable to copper ions (i.e., unsealed). That is, there is no liner between the first metal layer and dielectric material or there is a liner that is sufficiently thin and/or porous to allow for metal ion diffusion from the first metal layer into the dielectric fill material(s) under certain applied electric field. Additionally, the surface of the first metal layer at this interface can be oxidized to allow for easier copper ion generation under an electric field.

The device can also comprise a second metal layer adjacent to the cell on the second side. The interface between the second metal layer and the dielectric fill material(s) is non-permeable to copper ions (i.e., sealed). For example, the device can comprise a diffusion barrier layer at this second interface that is adapted to ensure that the second interface is non-permeable.

It is anticipated that the first metal layer (i.e., the metal layer that is not sealed from the dielectric fill material(s) within the cell) can be positioned adjacent to the bottom surface of the cell and the second metal layer (i.e., the metal layer that is sealed from the dielectric fill material(s) within the cell) can be positioned adjacent to the top surface of the cell or vice versa, depending upon the processes used to form the device (see discussion below).

Thus, the device comprises two metal electrodes (e.g., copper electrodes), one sealed and one unsealed, separated by a cell filled with low-k dielectric material(s). The resistance of the dielectric fill material(s) in the cell between these electrodes can be selectively varied by using the electrodes as terminals to establish a desired electric field within the cell. Specifically, the resistance of the dielectric fill material(s) in the cell can be selectively varied by applying predetermined positive and negative voltages to the electrodes. Thus, the device can comprise a simple switch or programmable resistor. Additionally, by monitoring the resistance change, a two-state, two terminal, silicon technology compatible, flash memory device with a very simple tuning process can be created.

Also disclosed are embodiments of a method of forming the device, described above. One embodiment of the method describes the device being formed such that the unsealed metal layer is positioned adjacent to the bottom surface of the dielectric-filled cell, e.g., a dielectric-filled via, and such that the sealed metal layer is positioned adjacent to the top surface of the dielectric-filled cell. Whereas, another embodiment of the method describes the device being formed such that the sealed metal layer is positioned adjacent to the bottom surface of the dielectric-filled cell (e.g., dielectric-filled via) and such that the unsealed metal layer is positioned adjacent to the top surface of the dielectric-filled cell.

More particularly, one embodiment of the method comprises forming a metal layer (e.g., a copper layer) above a substrate. Then, an isolation layer can be formed above the metal layer. The material used to form the isolation layer can be a dielectric material that is pre-selected for optimal device design or a dielectric that is preselected for optimal integration into standard formation processes. For example, if device design is a priority, then the device will comprise two metal electrodes separated by a low-k dielectric-filled cell (e.g., a low-k dielectric-filled via). Thus, the material for the isolation layer in which the low-k dielectric-filled cell is formed should be selected from a group of dielectric materials, such as silicon nitride (SiN), that have a low copper ion diffusivity for copper and that adhere well to a low-k dielectrics. Whereas, if integration into standard processes is a priority, then the material for the isolation layer should comprise a standard inter-layer dielectric (ILD) material, such as low-k dielectrics or silicon dioxide (SiO₂).

After formation of the isolation layer, a cell hole (e.g., a via hole) can be formed through the isolation layer to expose the metal layer.

After the cell is formed, an optional oxidation process can be performed so as to oxidize the top surface of the metal layer exposed in the cell. Oxidation of the top surface of metal layer will enhance metal ion formation during subsequent field operation.

Additionally, after the cell is formed, the sidewalls of the cell can also optionally be lined with a diffusion barrier material. This can be accomplished, for example, by depositing a conformal layer of the diffusion barrier material into the cell and then, either removing or damaging the portion of the conformal layer at the bottom of the cell adjacent to the metal layer. The lining material used can comprise tantalum (Ta) or tantalum nitride (TaN), either of which provides a diffusion barrier and also enhances adhesion of the low-k dielectric fill material. Thus, if the isolation layer is formed from a standard ILD material, such as silicon dioxide (SiO₂) which allows for fast diffusion of copper ions, then this lining process would not be considered optional. Similarly, if the isolation layer is formed from the same low-k dielectric that is used to fill the cell, this lining process would not be considered optional as well.

After the optional oxidation and/or lining processes are completed, the cell can be filled with at least one dielectric material (e.g., a bulk low-k dielectric material with a relatively high copper ion diffusivity or with multiple layers of at least two different low-k dielectric materials that extend vertically through the cell) to provide multiple faster diffusion paths for the improvement of device operational speed.

Then, a diffusion barrier layer (e.g., a tantalum (Ta) or tantalum nitride (TaN) layer) can be formed above the isolation layer and the cell.

Once the diffusion barrier layer is formed, an additional metal layer can be formed on the diffusion barrier layer above the cell.

Thus, in this embodiment the device is formed such that the interface between the metal layer below the cell and the dielectric fill material(s) within the cell is unsealed and will subsequently allow migration of metal ions into the cell. Furthermore, the device is formed such that the interface between the additional metal layer above the cell and the dielectric fill material(s) within the cell is sealed and will not allow migration of metal ions into the cell.

Another embodiment of the method similarly comprises forming a metal layer, forming an isolation layer above the metal layer and forming a cell hole (e.g., a via hole) through the isolation layer to expose the metal layer, as described above.

In this embodiment, the sidewalls and bottom surface of the cell are then lined with a barrier diffusion material (e.g., a tantalum (Ta) or tantalum nitride (TaN)). This can be accomplished, for example, by depositing a conformal layer of the material. In this embodiment lining of the cell is not optional.

Once the cell is lined, it can be filed with at least one dielectric material (e.g., a bulk low-k dielectric material with a relatively high copper ion diffusivity or with multiple layers of at least two different low-k dielectric materials that extend vertically through the cell).

After the cell is filled, a cap layer (e.g., a barrier diffusion layer comprising, for example, tantalum (Ta) or tantalum nitride (TaN)) can be formed above the isolation layer and the cell. Then, an opening can be patterned and formed in the cap layer to expose a portion of the dielectric fill material(s) in the cell.

Next, an additional metal layer (e.g., a copper layer) can be formed on the cap layer and on the exposed portion of the dielectric fill material(s) in the cell.

Thus, in this embodiment the device is formed such that the interface between the metal layer below the cell and the dielectric fill material(s) within the cell is sealed and will not allow migration of metal ions into the cell. Furthermore, the device is formed such that the interface between the additional metal layer above the cell and the dielectric fill material(s) within the cell is unsealed and will subsequently allow migration of metal ions into the cell.

In both of these method embodiments the resistance of the dielectric fill material(s) in the cell can be selectively varied by using the metal layers as electrodes or terminals to establish a desired electric field within the cell and, thereby, to trigger metal ion (e.g., copper ion) migration. Specifically, the resistance of the dielectric fill material(s) in the cell can be selectively adjusted by applying predetermined positive and negative voltages to the metal layers, as discussed above. Thus, the formed device can comprise a simple switch or programmable resistor. Additionally, by monitoring the resistance change, a two-state, two terminal, silicon technology compatible, flash memory device with a very simple tuning process can be created.

These and other aspects of the embodiments of the invention will be better appreciated and understood when considered in conjunction with the following description and the accompanying drawings. It should be understood, however, that the following descriptions, while indicating preferred embodiments of the invention and numerous specific details thereof, are given by way of illustration and not of limitation. Many changes and modifications may be made within the scope of the embodiments of the invention without departing from the spirit thereof, and the embodiments of the invention include all such modifications.

### BRIEF DESCRIPTION OF THE DRAWINGS

The embodiments of the invention will be better understood from the following detailed description with reference to the drawings, in which:

FIG. 1 is a schematic diagram illustrating an embodiment of a structure 100 of the invention;

FIG. 2 is a schematic diagram illustrating an embodiment of an alternative structure 100 of the invention;

FIG. 3 is a schematic diagram illustrating a low-resistive state in the structure of FIG. 1;

FIG. 4 is a graph illustrating the resistive state of the structure of FIG. 1 as a function of applied current over time;

FIG. 5 is a schematic diagram illustrating a high-resistive state in the structure of FIG. 1;

FIG. 6 is a schematic diagram illustrating another embodiment of a structure 200 of the invention;

FIG. 7 is a side view schematic diagram illustrating a memory array that incorporates the structure of FIGS. 1, 2 or 6;

FIG. 8 is a top view schematic diagram illustrating the memory array of FIG. 7;

FIG. 9 is a flow diagram illustrating an embodiment of a method of forming the structure 100 of FIGS. 1-2;

FIG. 10 is a schematic diagram illustrating a partially completed structure of the invention;

FIG. 11 is a schematic diagram illustrating a partially completed structure of the invention;

FIG. 12 is a schematic diagram illustrating a partially completed structure of the invention;

FIG. 13 is a schematic diagram illustrating a partially completed structure of the invention;

FIG. 14 is a schematic diagram illustrating a partially completed structure of the invention;

FIG. 15 is a schematic diagram illustrating a partially completed structure of the invention;

FIG. 16 is a schematic diagram illustrating a partially completed structure of the invention;

FIG. 17 is a flow diagram illustrating a method of performing process 914 of FIG. 9;

FIG. 18 is a schematic diagram illustrating a partially completed structure of the invention;

FIG. 19 is a schematic diagram illustrating a partially completed structure of the invention;

FIG. 20 is a schematic diagram illustrating a partially completed structure of the invention;

FIG. 21 is a schematic diagram illustrating a partially completed structure of the invention;

FIG. 22 is a schematic diagram illustrating a partially completed structure of the invention;

FIG. 23 is a schematic diagram illustrating a partially completed structure of the invention;

FIG. 24 is a flow diagram illustrating an embodiment of a method of forming the structure 200 of FIG. 6;

FIG. 25 is a schematic diagram illustrating a partially completed structure of the invention;

FIG. 26 is a schematic diagram illustrating a partially completed structure of the invention; and

FIG. 27 is a schematic diagram illustrating a partially completed structure of the invention.

### DETAILED DESCRIPTION OF PREFERRED EMBODIMENTS

The embodiments of the invention and the various features and advantageous details thereof are explained more fully with reference to the non-limiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the embodiments of the invention. The examples used herein are intended merely to facilitate an understanding of ways in which the embodiments of the invention may be practiced and to further enable those of skill in the art to practice the embodiments of the invention. Accordingly, the examples should not be construed as limiting the scope of the embodiments of the invention.

As mentioned above, there is a need in the art for a device (e.g., a programmable resistor) that is both field programmable and can be incorporated into a non-volatile memory array in a manner similar to that of a PCE such that it overcomes the limits of current SRAM and DRAM technology (i.e., such that it exhibits fast write and read, it is capable of high write/erase cycles, it is silicon technology compatibility, it exhibits soft error immunity, it is capable of scaling, etc.). To solve the problems associated with prior art memories, the present invention takes advantage of the diffusion properties of copper and other such metals through dielectrics which heretofore have caused problems. For example, copper (Cu) ions have been recognized as fast diffusers in low-k materials under electrical field. This diffusion has caused serious leakage problems. When atomic Cu penetrates into an inter-layer dielectric (ILD), it is usually in a Cu+ ion format, which brings the local potential energy low and negative and, thereby, makes the local molecules stable. The tendency for Cu to diffuse into the dielectric has been attributed to enthalpy of formation of CU-oxygen bond. Therefore, to prevent Cu from diffusing into dielectrics, Cu must be fully sealed using a diffusion barrier (e.g., a tantalum (Ta) layer or a tantalum nitride (TaN) layer).

The, the present invention however utilizes metal ion migration through dielectrics (e.g., Cu ion migration in low-k dielectrics) under controllable conditions to form a programmable resistor or switch.

Specifically, disclosed herein are embodiments of a device and an associated method of forming the device. The embodiments of the device comprise two metal electrodes (e.g., copper (Cu) electrodes) separated by one or more different dielectric materials (e.g., a glassy low-k dielectric, such as SiCOH and SiLK). One of the metal electrodes is sealed from the dielectric material and the other is not. The device is adapted to allow controlled migration of embedded metal ions (e.g., Cu ions) from the unsealed electrode into the dielectric material to form a conductive path under field between the electrodes in a matter of nanoseconds and, thereby, to decrease the resistance of the dielectric material. Reversing the field causes the metal ions to reverse their migration, to break the conductive path, and thereby, to increase the resistance of the dielectric material. Thus, the device can comprise a simple switch or programmable resistor. Additionally, by monitoring the resistance change, a two-state, two-terminal, silicon technology-compatible, flash memory device with a very simple tuning process can be created.

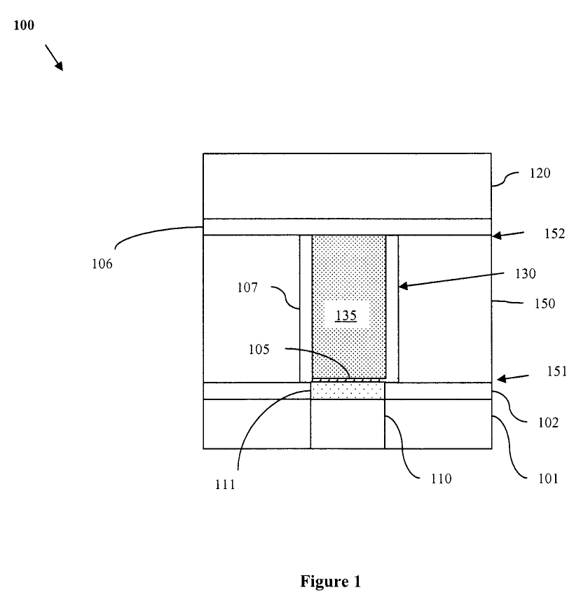

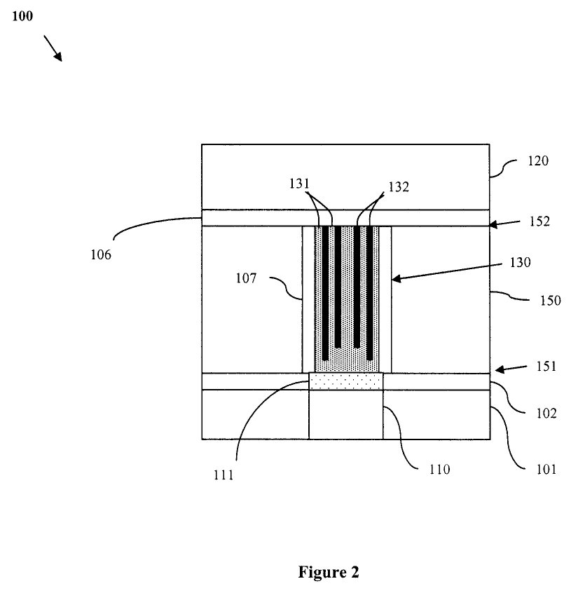

More particularly, referring to FIGS. 1 and 2, an embodiment 100 of the device can comprise an isolation layer 150 having a first side 151 and a second side 152. A cell 130 (e.g., a via) can extend through the isolation layer 150 from the first side 151 to the second side 152. This cell 130 can be filled with a bulk dielectric material 135 (see FIG. 1) or, alternatively, can be filled with multiple layers 131, 132 of at least two different dielectric materials extending vertically between the first side 151 and the second side 152 (see FIG. 2).

The material that forms the isolation layer 150 and the dielectric fill material(s) (e.g., 135 of FIG. 1 or 131, 132 of FIG. 2) within the cell 130 can comprise different materials. For example, the dielectric fill material(s) within the cell 130 can comprise low-k dielectric material(s) (e.g., SiLK, carbon doped oxide (SiCOH), benzocyclobutene (BCB), poly (arylene ether) (PAE-2) etc.) through which carbon rapidly diffuses (i.e., low-k materials that have a relatively high copper ion diffusivity). Whereas, the isolation layer 150 can comprise a material that has a relatively low copper ion diffusivity, such as silicon nitride (SiN), silicon carbide (SiC), silicon dioxide (SiO₂), silicon oxy-nitride (SiON), NBLOCK, etc. Preferably, a material, such as silicon nitride (SiN), which has good barrier properties and also adheres well to low-k dielectrics is used.

Optionally, the sidewalls of the cell 130 can be lined with a material, such as tantalum (Ta) or tantalum nitride (TaN), which provides a copper ion diffusion barrier and that enhances adhesion of the low-k dielectric fill material(s) (e.g., 135 of FIG. 1 or 131, 132 of FIG. 2) within the cell 130. More particularly, lining the cell sidewalls, allows the isolation layer 150 to be formed using a conventional inter-layer dielectric (e.g., silicon dioxide (SiO₂), which generally also allows for fast diffusion of copper ions). Lining the cell sidewalls, also allows the same low-k dielectric material to be used in both the isolation layer 150 and the cell 130 without risking copper diffusion into the isolation layer 150.

The device 100 can further comprise a first metal layer 110 (e.g., a metal electrode, such as a copper electrode) adjacent to the cell 130 on the first side 151. A cap layer 102 (e.g., a silicon nitride (SiN) or silicon carbide (SiC) layer) can ensure that the first metal layer 110 is isolated from the isolation layer 150. The interface between the first metal layer 110 and the dielectric fill material(s) (i.e., the first interface) is permeable (i.e., unsealed). That is, there is no liner between the first metal layer 110 and dielectric fill material(s) or there is an optional liner 105 (e.g., a tantalum (Ta) or tantalum nitride (TaN) liner) that is sufficiently thin and/or porous to allow for metal ion diffusion from the first metal layer 110 into the dielectric fill material(s). Additionally, the surface of the first metal layer 110 at this interface can be oxidized to provide Cu ions (i.e., the first metal layer 110 comprises an oxidized surface 111 that is adjacent to the dielectric fill material(s)). Those skilled in the art will recognize that copper ions are more easily generated in an electric field if the surface is oxidized.

The device 100 can also comprise a second metal layer 120 adjacent to the cell 130 on the second side 152. The interface between the second metal layer 152 and the dielectric fill material(s) (i.e., the second interface) is non-permeable (i.e., sealed). For example, the device 100 can comprise a copper ion diffusion barrier layer 106 at this second interface that is adapted to ensure that the second interface is non-permeable. The diffusion barrier layer 106 can, for example, comprise a relatively thick tantalum (Ta), tantalum nitride (TaN) layer or silicon carbon nitride (SiCN) dielectric capping layer.

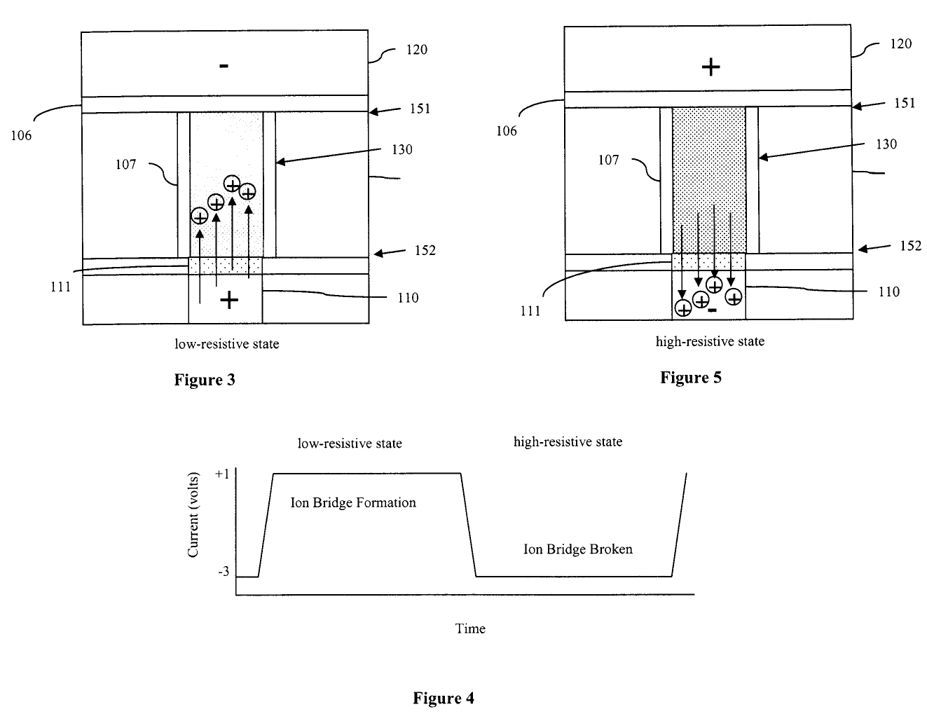

Thus, the device 100 comprises two metal electrodes 110, 120 (e.g., copper electrodes), one unsealed and one sealed, separated by dielectric material(s) (e.g., low-k dielectric material(s) having a relatively high copper ion diffusivity) in a cell 130, such as a via. The resistance of the dielectric fill material(s) in the cell 130 between these electrodes can be selectively varied by using the electrodes as terminals to establish a desired electric field within the cell 130. Specifically, the resistance of the dielectric fill material(s) e.g., 135 of FIG. 1 or 131, 132 of FIG. 2) in the cell 130 can be selectively varied by applying predetermined positive and negative voltages to the electrodes (i.e., to the first and second metal layer). For example, applying a positive voltage (e.g., a +1V) to an unsealed copper electrode 110 and a negative voltage to a sealed copper electrode 120 causes copper ions to migrate into the dielectric material, creating a conductive path between the electrodes 110, 120 and placing the dielectric material in a low-resistive state (i.e., a write state) (see FIGS. 3-4). Whereas, applying a negative voltage (e.g., −3Vs) to the unsealed copper electrode 110 and a positive voltage to the sealed copper electrode 120 causes the copper ions to migrate back towards the unsealed electrode 110, breaking the conductive path and placing dielectric material in a high-resistive state (i.e., an erase state) (see FIGS. 4-5). A small sensing voltage, for example, of less than 0.5 volts for both on and off state detection can be used to guarantee no change of the actual programming state. Thus, the device 100 can comprise a simple switch or programmable resistor.

It should be noted that copper (Cu) ion diffusion/drift behavior depends on local chemical environments such as cross linking and polarity of different molecular bond configurations. Therefore, by selecting low-k materials with relatively high Cu+ ion diffusion coefficients, faster switch On and OFF speed can be achieved. More particularly, by selecting dielectric fill material(s) comprising low-k dielectrics with relatively high copper ion diffusivity (e.g., SiLK, carbon doped oxide (SiCOH), benzocyclobutene (BCB), poly(arylene ether) (PAE-2) etc.)) faster switch-on speed can be achieved. On-time is estimated by the copper ion travel time through the dielectric fill material using the formula t=h/v, where t is travel time, h is the height of the cell (e.g., the height of the via) and v is the voltage of the electric field. Thus, cells 130 having the same height, but filled with different bulk low-k dielectrics having different copper ion diffusivities will exhibit different travel times t when subjected to the same electric field. For example, 100 nm vias subjected to the same electric fields but filled with the following bulk dielectric materials may exhibit the following different on-times: (1) a dielectric organic semiconductor fill, such as 2-amino-4,5-imidazoledicarbonitrile (AIDCN) may result in a 0.02 second on-time; (2) a SiLK dielectric fill may result in a 20 nanosecond on-time; (3) a benzocyclobutene (BCB) dielectric fill may result in a 0.2 nanosecond on-time; and (4) a poly(arylene ether) (PAE-2) dielectric fill may result in a 200 nanosecond on-time. The off-time for any of these dielectric fills can be in nanoseconds as that all that is required for turning off is breaking of the conductive path (i.e., breaking the ion accumulation bridge). Both the on and off speeds can be selectively modulated by varying the electric field, the temperature, the cell height, etc. Furthermore, copper ions will travel faster along an interface between two dielectrics rather than through a bulk dielectric. Thus, in order to further enhance on-time speeds, the device 100 can be configured as in FIG. 2 with multiple layers 131, 132 of different low-k dielectrics that extend vertically between the two electrodes 110, 120 creating multiple low-k hetero interfaces.

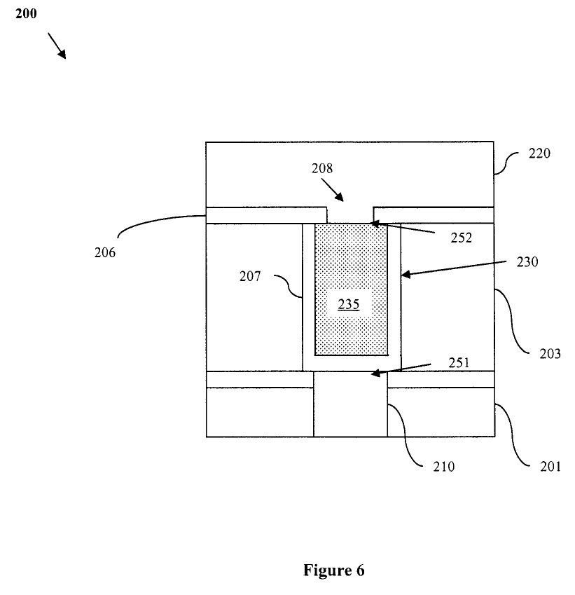

It should be noted that, as illustrated in FIGS. 1 and 2, the metal layer that is not sealed from the dielectric fill material(s) within the cell 130 (i.e., first metal layer 110) can be positioned adjacent to the bottom surface of the cell 130 and the metal layer that is sealed from the dielectric fill material(s) within the cell 130 (i.e., the second metal layer 120) can be positioned adjacent to the top surface of the cell 130. However, depending upon the processes used to form the device (see discussion below), it is also anticipated that the reverse can be true. For example, referring to FIG. 6, in another embodiment 200 the device similarly comprises two metal electrodes 210, 220 (e.g., copper electrodes), separated by a cell 230 (e.g., a via). As with embodiment illustrated in FIGS. 1 and 2, the cell 230 can be filled with one or more low-k dielectric material(s) having a relatively high copper ion diffusivity. The resistance of the dielectric fill material(s) in the cell 230 between these electrodes can be selectively varied by using the electrodes as terminals to establish a desired electric field within the cell 230. However, in this case the sidewalls and bottom surface of the cell 230 are lined with a barrier diffusion material 207 and an opening 208 is formed in a cap layer 206 above the cell 230 such that the metal layer 220 contacts the dielectric material(s) in the cell 230. Thus, the bottom electrode 210 is sealed to the dielectric material(s) within the cell 230 and the top electrode 220 is unsealed.

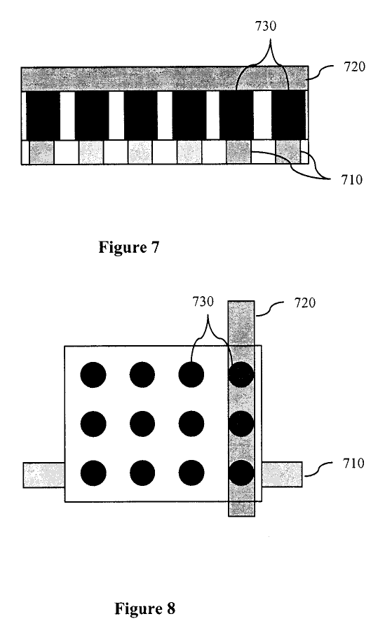

Additionally, by monitoring the resistance change, a two-state, two terminal, silicon technology compatible, flash memory device with a very simple tuning process can be created. More specifically, referring to FIGS. 7 and 8 in combination, a plurality of these devices can be incorporated into a stackable back end of the line (BEOL) memory 700. That is dielectric filled cells 730 (i.e., memory cells) can electrically connected between an array of word lines 710 formed in a metal layer (Mx) and bit lines 720 formed in the next metal layer (Mx+1), where the cells 730 are sealed to either the word lines or the bit lines. Thus, the word lines 710 and bit lines 720 effectively function as shared first and second electrodes by column and row.

Also disclosed are embodiments of a method of forming the device, described above. One embodiment of the method describes the device 100 being formed such that the unsealed metal layer is positioned adjacent to the bottom surface of the dielectric-filled cell (e.g., a dielectric-filled via) and such that the sealed metal layer is positioned adjacent to the top surface of the dielectric-filled cell, as illustrated in FIGS. 1 and 2. Whereas, another embodiment of the method describes the device 200 being formed such that the sealed metal layer is positioned adjacent to the bottom surface of the dielectric-filled cell and such that the unsealed metal layer is positioned adjacent to the top surface of the dielectric-filled cell, as illustrated in FIG. 6.

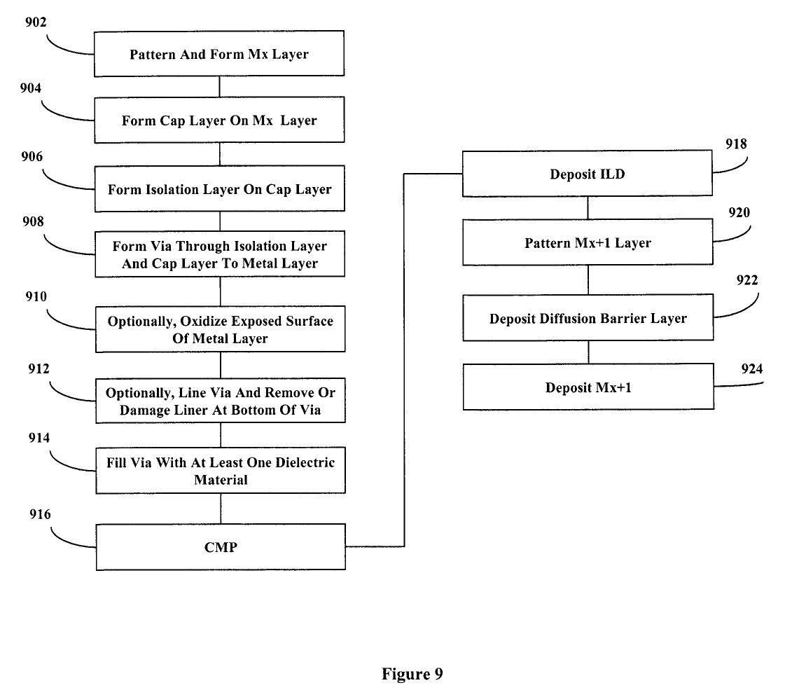

More particularly, referring to FIG. 9, one embodiment of the method comprises forming metal layer (e.g., a copper layer) above a substrate (902). For example, copper lines 110 can be patterned and formed in an interlayer dielectric (ILD) 101 using conventional single damascene/dual damascene back end of the line metal layer (Mx) formation techniques.

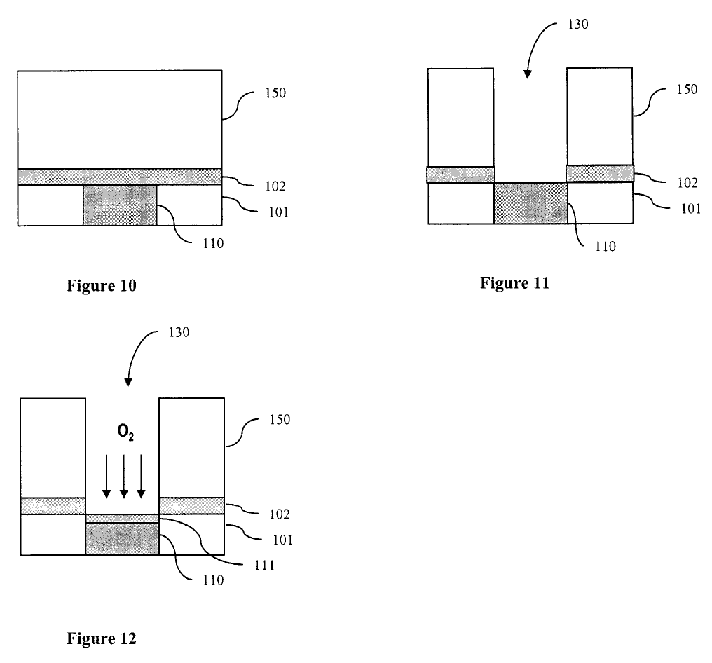

After the Mx layer formation at process 902, a cap layer 102 (e.g., a silicon nitride layer) can be formed (e.g., deposited) above the copper lines 110 and ILD 101 (904, see FIG. 10).

Then, an isolation layer 150 can be formed (e.g., deposited) above the cap layer 102 (906, see FIG. 10). The material used to form the isolation layer 150 can be a dielectric material that is pre-selected for optimal device design or preselected for optimal integration into standard formation processes. For example, if device design is a priority, then the device will comprise two metal electrodes separated by a low-k dielectric-filled cell. Thus, the material for the isolation layer in which the low-k dielectric-filled cell is formed should be selected from a group of dielectric materials, such as silicon nitride (SiN), that have a low copper ion diffusivity for copper and that adhere well to a low-k dielectrics. Whereas, if integration into standard processes is a priority, then the material for the isolation layer should comprise a standard inter-layer dielectric (ILD) material, such as silicon dioxide (SiO₂) or low-k dielectrics.

After formation of the isolation layer 150 at process 906, a cell 130 (e.g., a via hole) can be formed (e.g., patterned and etched, using conventional processing techniques) through the isolation layer 150 and cap layer 10 to expose the metal layer 110 below (908, see FIG. 11).

After the cell 130 is formed at process 908, an optional oxidation process can be performed so as to oxidize the top surface 111 of the metal layer 110 exposed in the cell 130 (910, see FIG. 12). Oxidation of the top surface of metal layer will enhance metal ion generation during subsequent device operation.

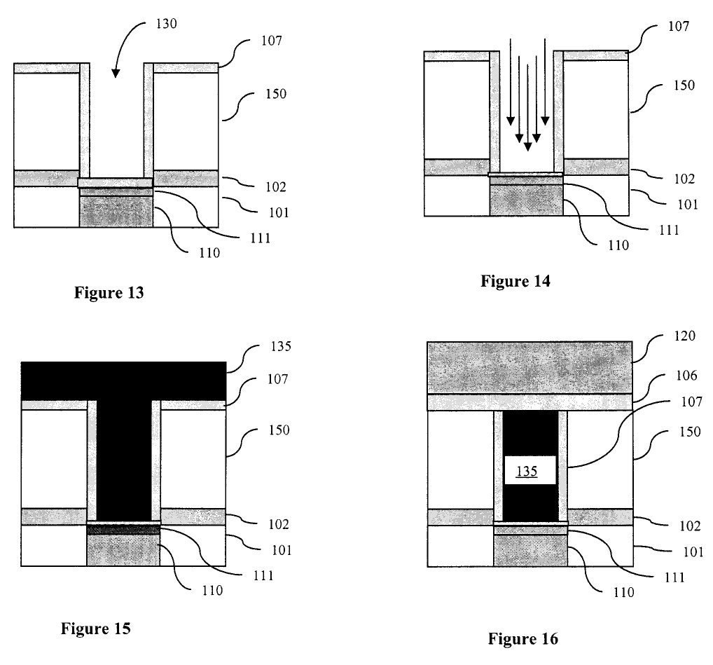

Additionally, after the cell 130 is formed, the sidewalls of the cell 130 can also optionally be lined with a diffusion barrier material 107 (912). This can be accomplished, for example, by depositing a conformal layer of the diffusion barrier material into the cell 130 and then, either removing (e.g., by etchback) or damaging (e.g., by sputtering) the portion of the conformal layer 107 at the bottom of the cell 130 adjacent to the metal layer 110 (see FIGS. 13-14). Damaging or removing the lining at the bottom of the cell ensures that the metal layer 110 will not be sealed from the subsequently deposited dielectric material. The lining material used can comprise tantalum (Ta) or tantalum nitride (TaN), either of which provides a diffusion barrier and also enhances adhesion of the low-k dielectric fill material. Thus, if the isolation layer 150 is formed from a standard ILD material, such as silicon dioxide (SiO₂) which generally also allows for fast diffusion of copper ions, or from the same low-k dielectric as the dielectric used to subsequently fill the cell at process 914, then this lining process would not be considered optional.

After the optional oxidation and/or lining processes 910-912 are completed, the cell 130 can be filled with at least one dielectric material (914). For example, a bulk low-k dielectric material with a relatively high copper ion diffusivity can be deposited into the cell (see FIG. 15).

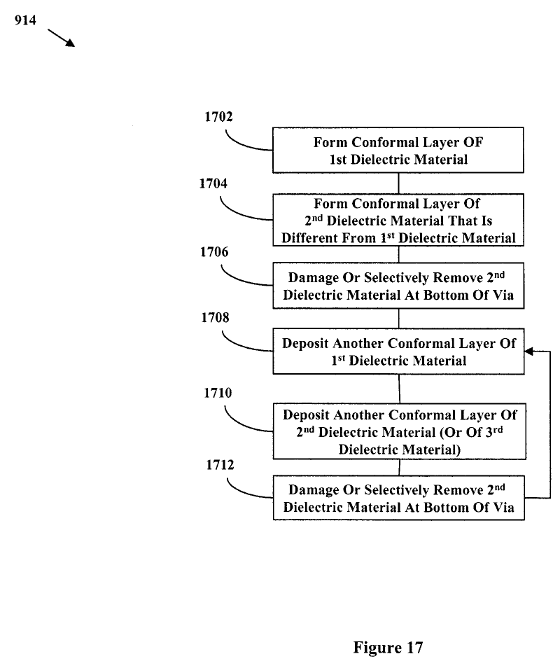

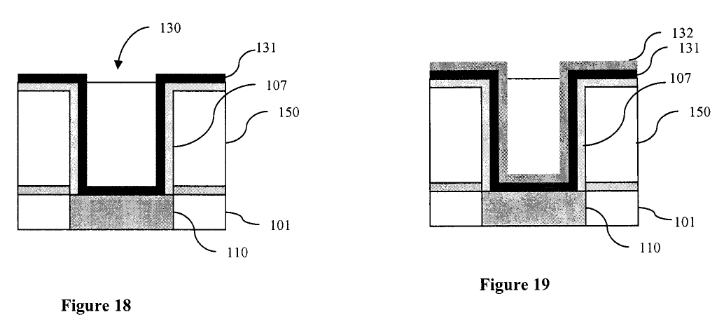

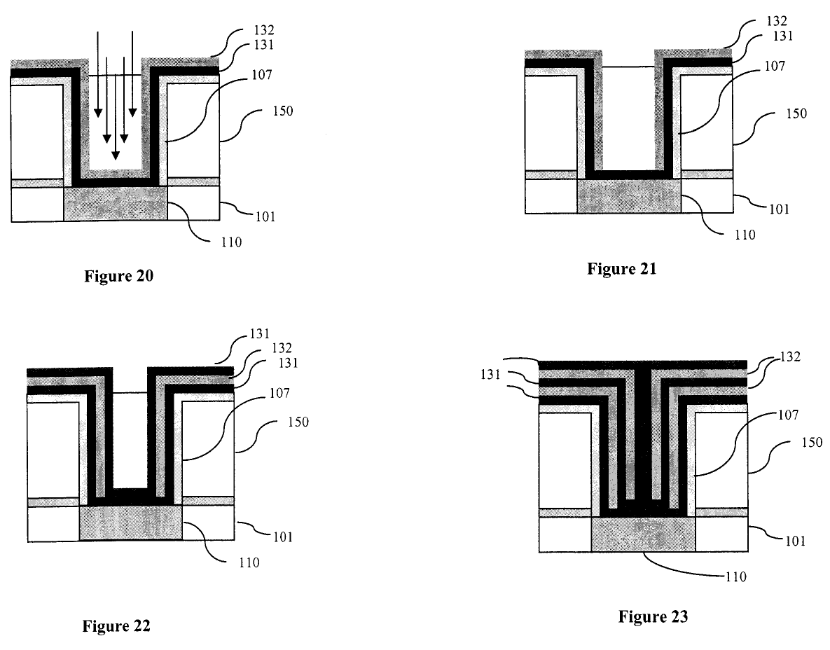

Alternatively, referring to FIG. 17, additional process steps can be performed so that the cell is filled with multiple layers of at least two different low-k dielectric materials that extend vertically through the cell (as in FIG. 2)). Specifically, a first conformal layer of a low-k dielectric material 131 can be deposited (e.g., by chemical vapor deposition (CVD) into the cell 130 (1702, see FIG. 18). Then, a second conformal layer of a different low-k dielectric 132 can be deposited (e.g., by CVD) onto the first conformal layer (1704, see FIG. 19). After the second conformal layer is deposited, it is damaged (e.g., by sputtering) or selectively removed (e.g., etched back) from the bottom of the cell, exposing the first dielectric material (1706, see FIGS. 20-21). Then, another conformal layer of the first dielectric material is deposited, another conformal layer of the second dielectric material is deposited, and the second dielectric material is again damaged or removed from the bottom of the cell, exposing the first dielectric material. These processes are repeated until the cell is filled (1708-1712, see FIGS. 22-23).

Note that the purpose of the multiple layers of low-k dielectric is to create interface at which copper ions will travel faster. While formation of these interfaces can be accomplished using layers of different low-k dielectrics, such interfaces can also be accomplished by depositing multiple conformal layers of the same dielectric material and between deposition processes treating the exposed surface of each layer.

Referring again to FIG. 9, once the cell 130 is filled a polishing process (e.g., a conventional chemical mechanical polishing (CMP) process) is performed to remove any dielectric fill material and liner material from above the isolation layer 150 (916).

Then, another interlayer dielectric (ILD) layer is deposited and the second metal layer 120 (e.g., Mx+1) is patterned in the ILD so that the cell 130 is exposed (918-920).

Next, a diffusion barrier layer 106 (e.g., a tantalum (Ta) or tantalum nitride (TaN) layer) can be formed (e.g., deposited), followed by an additional metal layer 220 (922-924, see FIG. 16).

Thus, as illustrated in FIGS. 1 and 2, in this embodiment the device 100 is formed such that the interface 151 between the metal layer 110 below the cell 130 and the dielectric fill material(s) (135 of FIG. 1 or 131-132 of FIG. 2) within the cell 130 is unsealed and will subsequently allow migration of metal ions into the cell 130 when biased. Furthermore, the device 100 is formed such that the interface 152 between the additional metal layer 120 above the cell 130 and the dielectric fill material(s) within the cell 130 is sealed and will not allow migration of metal ions into the cell 130.

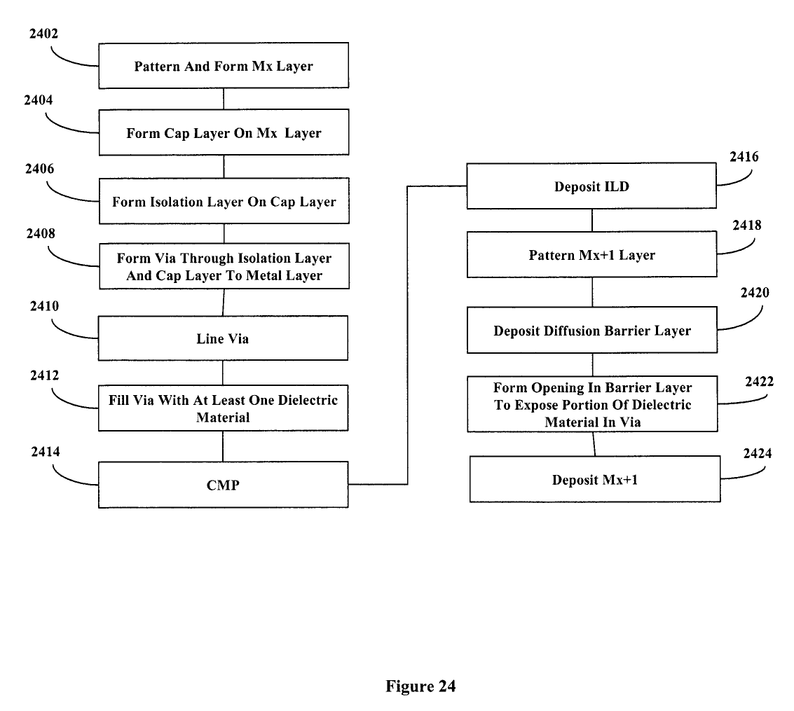

Referring to FIG. 24, another embodiment of the method similarly comprises forming a metal layer 220, forming a cap layer 202 above the metal layer 220, forming an isolation layer 250 above the metal layer 220 and forming a cell 230 (e.g., a via hole) through the isolation layer 250 and cap layer 202 to expose the metal layer 210, as described above (2402-2408).

In this embodiment, the sidewalls and bottom surface of the cell are then lined with a barrier diffusion material 207 (e.g., a tantalum (Ta) or tantalum nitride (TaN)) (2410). This can be accomplished, for example, by depositing a conformal layer of the material. In this embodiment lining of the cell is not optional and no processes (e.g., sputtering or etchback) are used to damage or removed the liner 207 from the bottom of the cell.

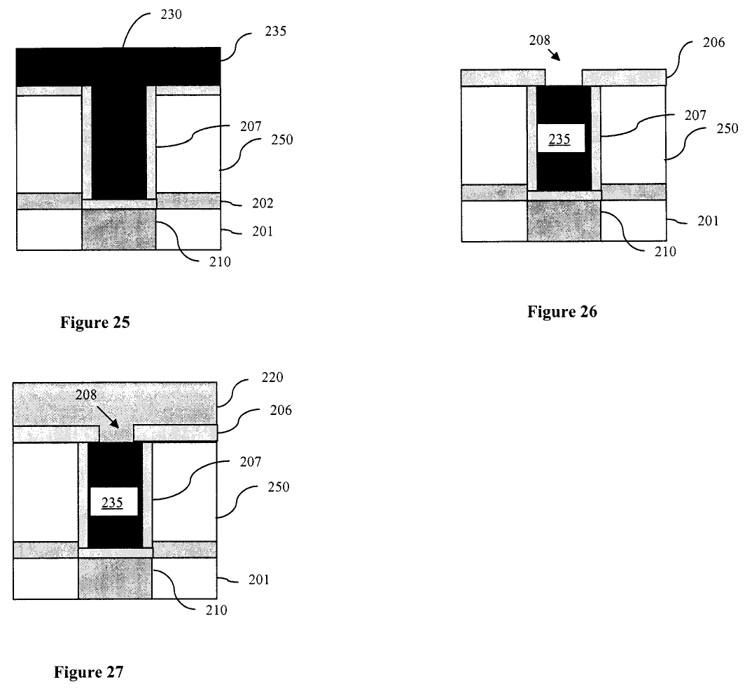

Once the cell 230 is lined, it can be filled with at least one dielectric material, as discussed above in the previous method embodiment (2412). For example, the cell 230 can be filled with a bulk low-k dielectric material 235 with a relatively high copper ion diffusivity (see FIG. 25). Alternatively, the cell 230 can be filled with multiple layers of at least two different low-k dielectric materials that extend vertically through the cell, as discussed above and described in the flow diagram of FIG. 17.

After the cell 230 is filled at process 2412, another interlayer dielectric (ILD) layer is deposited and the second metal layer 220 (e.g., Mx+1) is patterned in the ILD so that the cell 230 is exposed (2416-2418). Then, a cap layer 206 (e.g., a barrier diffusion layer comprising, for example, a SiCN dielectric capping layer, can be formed (e.g., deposited) and an opening 208 can be patterned and formed in the cap layer 206 to expose a portion of the dielectric fill material(s) 235 in the cell 230 (2420-2422, see FIG. 26).

Next, an additional metal layer (e.g., a copper layer) 220 can be formed on the cap layer 206 and on the exposed portion of the dielectric fill material(s) 235 in the cell 230 (2424, see FIG. 27).

Thus, as illustrated in FIG. 6, in this embodiment the device 200 is formed such that the interface 251 between the metal layer 210 below the cell 230 and the dielectric fill material(s) 235 within the cell 230 is sealed and will not allow migration of metal ions into the cell 230. Furthermore, the device 200 is formed such that the interface 252 between the additional metal layer 220 above the cell 230 and the dielectric fill material(s) 235 within the cell 230 is unsealed and will subsequently allow migration of metal ions into the cell 230 when biased.

In both of these method embodiments, the resistance of the dielectric fill material(s) in the cell can be selectively varied by using the metal layers as electrodes or terminals to establish a desired electric field within the cell. Specifically, the resistance of the dielectric fill material(s) in the cell can be selectively adjusted by applying predetermined positive and negative voltages to the metal layers, as discussed above. Thus, the formed device can comprise a simple switch, programmable resistor, or a vertical memory cell. Additionally, by monitoring the resistance change, a two-state, two-terminal, silicon technology compatible, flash memory device with a very simple tuning process can be created.

This device is advantageous over prior art devices, such as phase change elements, because it is a low power device that can be scaled with technology node and, during operation, it won't generate Joule heating or self-heating. Furthermore, this device is formed at the interconnect level, so it does not occupy any active semiconductor surface (e.g., any silicon surface) and so it can be stacked up vertically at different interconnect levels. Therefore, the device can be incorporated into a high density and high compact memory array or switch array that can easily be formed without the silicon surface space limitations that are currently experienced by static random access memory arrays (SRAMs) and dynamic random access memory arrays (DRAMs).

Therefore, disclosed above are embodiments of a device and method of forming the device that utilize metal ion migration under controllable conditions. The device embodiments comprise two metal electrodes separated by one or more different dielectric materials. One electrode is sealed from the dielectric material, the other is not. The device is adapted to allow controlled migration of embedded metal ions from the unsealed electrode into dielectric material to form a conductive path under field between the electrodes and, thereby, to decrease the resistance of the dielectric material. Reversing the field causes the metal ions to reverse their migration, to break the conductive metallic path between the electrodes and, thereby, to increase the resistance of the dielectric material. Thus, the device can comprise a simple switch or programmable resistor. Additionally, by monitoring the resistance change, a two-state, two-terminal, silicon technology-compatible, flash memory device with a very simple tuning process can be created.

The foregoing description of the specific embodiments will so fully reveal the general nature of the invention that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments of the invention have been described in terms of preferred embodiments, those skilled in the art will recognize that the embodiments of the invention can be practiced with modification within the spirit and scope of the appended claims.

What is claimed is:

1. A device comprising:
an isolation layer having a first side and a second side;
a cell extending through said isolation layer from said first side to said second side, wherein said cell is filled with at least one dielectric material;
a first metal layer adjacent to said cell on said first side, wherein a first interface between said first metal layer and said dielectric material is permeable;
a second metal layer adjacent to said cell on said second side, wherein a second interface between said second metal layer and said dielectric material is non-permeable.

2. The device of claim 1, wherein a resistance of said dielectric material can be selectively varied by selectively applying predetermined voltages to said first metal layer and said second metal layer.

3. The device of claim 2, wherein applying different predetermined voltages to said first metal layer and said second metal layer alters metal ion migration in said dielectric material so as to selectively vary said resistance.

4. The device of claim 1, wherein said first metal layer comprises copper.

5. The device of claim 1, wherein said at least one dielectric material comprises a dielectric material with a relatively high copper ion diffusivity and wherein said isolation layer comprises a different dielectric material with a relatively low copper ion diffusivity.

6. The device of claim 1, wherein sidewalls of said cell are lined with a barrier material.

7. The device of claim 6, wherein said at least one dielectric material comprises one of a same dielectric material as said isolation layer and a different dielectric material with a relatively high metal ion diffusivity.

8. The device of claim 1, wherein said at least one dielectric material comprises multiple layers of at least two different dielectric materials extending vertically between said first side and said second side.

9. The device of claim 1, wherein said first metal layer comprises an oxidized surface at said first interface.

10. A method of forming a device comprising:
forming an initial metal layer;
forming an isolation layer above said initial metal layer;
forming a cell through said isolation layer to expose said initial metal layer;
filling said cell with at least one dielectric material;
forming a diffusion barrier layer above said isolation layer and said cell; and
forming an additional metal layer on said diffusion barrier layer above said cell.

11. The method of claim 10, further comprising selectively adjusting a resistance of said at least one dielectric material by selectively applying predetermined voltages to said initial metal layer and said additional metal layer.

12. The method of claim 11, wherein applying different predetermined voltages to said initial metal layer and said additional metal layer alters metal ion migration through said dielectric material so as to selectively vary said resistance.

13. The method of claim 10, wherein said metal layer is formed with copper, wherein said at least one dielectric material comprises a low-k dielectric material with a relatively high copper ion diffusivity and wherein said isolation layer has a relatively low copper ion diffusivity.

14. The method of claim 10, further comprising before said filling of said cell, lining sidewalls of said cell with a diffusion barrier material.

15. The method of claim 13, wherein said lining of said sidewalls of said cell comprises, depositing a conformal layer of said diffusion barrier material in said cell and one of removing and damaging said conformal layer adjacent to said metal layer.

16. The method of claim 10, wherein said filling of said cell comprises filling said cell with multiple layers of at least two different dielectric materials extending vertically through said cell.

17. The method of claim 10, further comprising, before said filling of said cell, performing an oxidation process so as to oxidize said initial metal layer exposed in said cell.

18. A method of forming a device comprising:
forming an initial metal layer;
forming an isolation layer above said initial metal layer;
forming a cell through said isolation layer to expose said initial metal layer;
lining said cell with a barrier diffusion material;
filling said cell with a dielectric material;
forming a cap layer above said isolation layer and said cell;
forming an opening in said cap layer to expose a portion of said dielectric material in said cell; and
forming an additional metal layer on said cap layer and on said portion said dielectric material.

19. The method of claim 16, further comprising selectively adjusting a resistance of said dielectric material by selectively applying predetermined voltages to said initial metal layer and said additional metal layer so that metal ion migration through said dielectric material is altered.

20. The method of claim 10, wherein said filling of said cell comprises filling said cell with a low-k dielectric material having a relatively high copper ion diffusivity.
